(19) United States
(12) Patent Application Publication
(10) Pub. No.: US 2026/0332160 A1
(43) Pub. Date: Oct. 22, 2026

(54) COMPRESSION METHOD BASED ON ARTIFICIAL INTELLIGENCE AND DEVICE THEREFOR

(71) Applicant: SAMSUNG ELECTRONICS CO., LTD., Suwon-si (KR)

(72) Inventors: Seunghoon JEE, Suwon-si (KR); Paul OH, Suwon-si (KR); Chansol HWANG, Suwon-si (KR); Dokwan OH, Suwon-si (KR); Junhee LEE, Suwon-si (KR)

(73) Assignee: SAMSUNG ELECTRONICS CO., LTD., Suwon-si (KR)

(21) Appl. No.: 19/421,351

(22) Filed: Dec. 16, 2025

(30) Foreign Application Priority Data
Apr. 22, 2025 (KR) 10-2025-0052627
Jun. 25, 2025 (KR) 10-2025-0084370

(51) Int. Cl. H03M 7/30; G06N 3/04

(52) U.S. Cl. CPC H03M 7/3071; G06N 3/04; H03M 7/6005; H03M 7/6023

(57) ABSTRACT

A processor-implemented method performed by a memory device includes receiving a read request for target data from a host; reading a compression bitstream corresponding to the target data from a memory; predicting, at a first time point, a second probability distribution of a second data symbol of the target data by performing a neural probability distribution prediction based on a first previous data symbol group of the target data, determined by decompression of a time point interval previous to the first time point; and determining, at a second time point later than the first time point, the second data symbol by decompressing the compression bitstream according to entropy decoding based on the compression bitstream and the second probability distribution.

### CROSS-REFERENCE TO RELATED APPLICATION

This application claims priority from Korean Patent Application No. 10-2025-0052627, filed on Apr. 22, 2025, and Korean Patent Application No. 10-2025-0084370, filed on Jun. 25, 2025, in the Korean Intellectual Property Office, the disclosures of which are incorporated by reference herein in their entireties.

### BACKGROUND

### 1. Field

The present disclosure relates to a compression method based on artificial intelligence (AI) and a device therefor.

### 2. Description of Related Art

Data compression is a technology for saving a storage space or improving transmission efficiency by reducing the number of bits required to represent digital data. Typically, the compression scheme may be divided into lossy compression and lossless compression. The lossless compression may be characterized by complete restoration of the original data. The lossless compression may be used for data where preservation of the original is important, such as text, a binary file, and genomic information. For example, LZ77, Huffman coding, and arithmetic coding are examples of the lossless compression. The lossless compression may improve a compression ratio by mainly analyzing a repetitive pattern or probability distribution based on statistical characteristics of the data. Recently, with the development of artificial intelligence technology, a compression scheme using a neural network has been emerging.

### SUMMARY

One or more embodiments may address at least the above problems and/or disadvantages and other disadvantages not described above. Also, the embodiments are not required to overcome the disadvantages described above, and an embodiment may not overcome any of the problems described above.

According to an aspect of the disclosure, a processor-implemented method performed by a memory device includes receiving a read request for target data from a host; reading a compression bitstream corresponding to the target data from a memory; predicting, at a first time point, a second probability distribution of a second data symbol of the target data by performing a neural probability distribution prediction based on a first previous data symbol group of the target data, determined by decompression of a time point interval previous to the first time point; and determining, at a second time point later than the first time point, the second data symbol by decompressing the compression bitstream according to entropy decoding based on the compression bitstream and the second probability distribution.

The method further includes predicting, at the second time point, a third probability distribution of a third data symbol of the target data by performing a neural probability distribution prediction based on a second previous data symbol group of the target data, determined by decompression of a time point interval previous to the second time point; and determining, at a third time point later than the second time point, the third data symbol by decompressing the compression bitstream according to entropy decoding based on the compression bitstream and the third probability distribution.

The determining of the second data symbol and the predicting of the third probability distribution are performed in parallel.

The method further includes receiving a write request for the target data from the host before receiving the read request; predicting each probability distribution of each data symbol of the target data by performing a neural probability distribution prediction based on a previous data symbol group of each data symbol of the target data; determining the compression bitstream by compressing each data symbol of the target data according to entropy encoding based on each probability distribution and each data symbol of the target data; and storing the compression bitstream in the memory.

The neural probability distribution prediction is performed by a neural model that uses a previous data symbol group including a predetermined number of data symbols as input data, in which the method further includes: determining a data symbol of the target data by decompressing the compression bitstream according to entropy decoding based on a predetermined probability distribution until the predetermined number of data symbols are secured before the first time point.

The predetermined number of data symbols are filled by decompression of the compression bitstream and one or more data paddings.

A neural model used for the neural probability distribution prediction includes a plurality of layers that do not have a recursion structure and a residual connection.

The predicting of the second probability distribution comprises, at the first time point, predicting the second probability distribution and a third probability distribution of the second data symbol and a third data symbol of the target data, by performing the neural probability distribution prediction based on the first previous data symbol group.

The method further includes: determining, at a third time point, the third data symbol by decompressing the compression bitstream according to entropy decoding based on the compression bitstream and the third probability distribution.

The predicting of the second probability distribution includes, at the first time point, predicting the second probability distribution and a third probability distribution of the second data symbol and a third data symbol of the target data, respectively, by performing the neural probability distribution prediction based on the first previous data symbol group.

The determining of the second data symbol comprises, at the second time point, determining the second data symbol and the third data symbol by decompressing the compression bitstream according to entropy decoding based on the compression bitstream, the second probability distribution, and the third probability distribution.

The compression bitstream is stored in a compressed memory space of the memory.

According to an aspect of the disclosure, a processor-implemented method performed by a host includes transmitting a read request for target data to a memory device; receiving a compression bitstream corresponding to the target data from the memory device; predicting, at a first time point, a second probability distribution of a second data symbol of the target data by performing a neural probability distribution prediction based on a first previous data symbol group of the target data, determined by decompression of a time point interval previous to the first time point; and determining, at a second time point later than the first time point, the second data symbol by decompressing the compression bitstream according to entropy decoding based on the compression bitstream and the second probability distribution.

The method further includes predicting, at the second time point, a third probability distribution of a third data symbol of the target data by performing a neural probability distribution prediction based on a second previous data symbol group of the target data, determined by decompression of a time point interval previous to the second time point; and determining, at a third time point later than the second time point, the third data symbol by decompressing the compression bitstream according to entropy decoding based on the compression bitstream and the third probability distribution.

A memory device includes: memory configured to store instructions; and one or more processors operatively coupled to the memory; in which the instructions, when executed by the one or more processors individually or collectively, cause the memory device to: receive a write request for target data from a host, read a compression bitstream corresponding to the target data from memory, predict, at a first time point, a second probability distribution of a second data symbol of the target data by performing a neural probability distribution prediction based on a first previous data symbol group of the target data, determined by decompression of a time point interval previous to the first time point, and determine, at a second time point later than the first time point, the second data symbol by decompressing the compression bitstream according to entropy decoding based on the compression bitstream and the second probability distribution.

The instructions, when executed by the one or more processors individually or collectively, cause the memory device to: predict, at the second time point, a third probability distribution of a third data symbol of the target data by performing a neural probability distribution prediction based on a second previous data symbol group of the target data, determined by decompression of a time point interval previous to the second time point, and determine, at a third time point later than the second time point, the third data symbol by decompressing the compression bitstream according to entropy decoding based on the compression bitstream and the third probability distribution.

The determining the second data symbol and the predicting the third probability distribution are performed in parallel.

The neural model used for the neural probability distribution prediction includes a plurality of layers that do not have a recursion structure and a residual connection.

The instructions, when executed by the one or more processors individually or collectively, cause the memory device to predict, at the first time point, the second probability distribution and a third probability distribution of the second data symbol and a third data symbol of the target data by performing the neural probability distribution prediction based on the first previous data symbol group.

The instructions, when executed by the one or more processors individually or collectively, cause the memory device to determine, at a third time point, the third data symbol by decompressing the compression bitstream according to entropy decoding based on the compression bitstream and the third probability distribution.

Additional aspects of embodiments will be set forth in part in the description which follows and, in part, will be apparent from the description, or may be learned by practice of the disclosure.

### BRIEF DESCRIPTION OF THE DRAWINGS

The above and/or other aspects will be more apparent by describing certain embodiments with reference to the accompanying drawings, in which:

FIG. 1 is a diagram illustrating an example of a process of compressing and decompressing target data, according to one or more embodiments;

FIG. 2 is a diagram illustrating operation timing of an arithmetic coder and a neural model in a process of decompressing target data, according to one or more embodiments;

FIG. 3 is a diagram illustrating an example of a decompression process using a predetermined probability distribution, according to one or more embodiments;

FIG. 4 is a diagram illustrating an example of a decompression process using padding data, according to one or more embodiments;

FIG. 5A is a diagram illustrating an example of a decompression process using a neural model for predicting probability distributions of a plurality of data symbols in a single cycle, according to one or more embodiments;

FIG. 5B is a diagram illustrating an example of a decompression process using a neural model for predicting probability distributions of a plurality of data symbols in multiple cycles, according to one or more embodiments;

FIG. 5C is a diagram illustrating an example of a decompression process using a neural model for predicting probability distributions of a plurality of data symbols in a single cycle and an arithmetic coder for performing decoding on the plurality of data symbols in the single cycle, according to one or more embodiments;

FIG. 5D is a diagram illustrating an example of a structure of a neural model, according to one or more embodiments;

FIG. 6 is a flowchart of a method performed by a memory device, according to one or more embodiments;

FIG. 7 is a diagram illustrating an example of an operation of a memory device based on a write request and a read request of a processor, according to one or more embodiments;

FIG. 8 is a flowchart of a method performed by a host, according to one or more embodiments; and

FIG. 9 is a diagram illustrating an example of a configuration of an electronic device, according to one or more embodiments.

### DETAILED DESCRIPTION

The following detailed structural or functional description is provided as an example only and various alterations and modifications may be made to the embodiments. Accordingly, the embodiments are not construed as limited to the disclosure and should be understood to include all changes, equivalents, and replacements within the idea and the technical scope of the disclosure.

Although terms, such as first, second, and the like are used to describe various components, the components are not limited to the terms. These terms should be used only to distinguish one component from another component. For example, a first component may be referred to as a second component, and similarly, the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component.

As used herein, the singular form is intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “A or B”, “at least one of A and B”, “at least one of A or B”, “A, B or C”, “at least one of A, B and C”, and “at least one of A, B, or C,” each of which may include any one of the items listed together in the corresponding one of the phrases, or all possible combinations thereof.

Unless otherwise defined, all terms, including technical and scientific terms, used herein have the same meaning as commonly understood by one of ordinary skill in the art to which the present disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. When describing the embodiments with reference to the accompanying drawings, like reference numerals refer to like elements and a repeated description related thereto will be omitted.

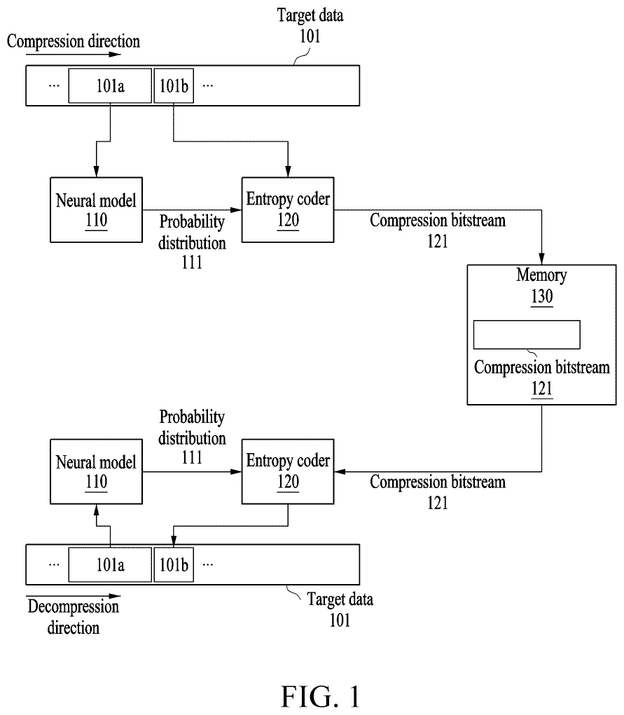

FIG. 1 is a diagram illustrating an example of a process of compressing and decompressing target data, according to one or more embodiments. Referring to FIG. 1, an electronic device (e.g., a host or a memory device) may determine a compression bitstream 121 by compressing target data 101 and may determine the target data 101 by decompressing the compression bitstream 121. The target data 101 may include symbols. For example, a symbol may include text data (e.g., a character), image data (e.g., a pixel value or a channel value), audio data (e.g., a digital sample value), but is not limited thereto. In one or more examples, reference to a first data symbol and to a second data symbol may refer to two different symbols in the target data. However, the first data symbol may be positioned before or after the second data symbol in the target data.

According to one or more embodiments, the electronic device may perform lossless compression. For example, the electronic device may perform entropy coding. The entropy coding may be a lossless compression scheme using an occurrence probability of each symbol in the target data 101. According to the entropy coding, a short code may be assigned to a symbol with a high occurrence probability, and a long code may be assigned to a symbol with a low occurrence probability. According to the entropy coding, data compression may be performed based on entropy defined in information theory. Depending on the compression scheme of the entropy coding, the number of bits of compressed data may be reduced.

For example, the entropy coding may include arithmetic coding. The arithmetic coding may compress the target data 101 into a real value within a real-number range. According to the arithmetic coding, the real-number range may decrease according to the occurrence probability of each symbol in the target data 101, and the target data 101 may be represented as one real value (e.g., the compression bitstream 121) in the decreased real-number range. In one or more examples, a real-number range may refer to a data set's spread of values such as, for example, all non-negative numbers (e.g., [0, ∞)).

The electronic device may compress (e.g., entropy coding or arithmetic coding) and decompress (e.g., entropy decoding or arithmetic decoding) using a neural model 110 and an entropy coder 120.

According to one or more embodiments, the neural model 110 and/or the entropy coder 120 (e.g., an arithmetic coder) may be implemented as digital circuitry separated from and/or integrated into a memory controller (e.g., a memory controller of the host or a memory controller of the memory device). For example, the neural model 110 and/or the entropy coder 120 may be physically implemented by analog and/or digital circuitry including at least one of a logic gate, an integrated circuit, a microprocessor, a microcontroller, a memory circuit, a passive electronic component, an active electronic component, an optical component, or a similar component thereto. For example, a field programmable gate array (FPGA) and/or an application-specific integrated circuit (ASIC) may be used to implement a custom logic, and the custom logic may perform at least a portion of a function of the neural model 110 and/or the entropy coder 120.

The neural model 110 may include a neural network. The neural model 110 may receive a data symbol group 101a including a predetermined number of data symbols and may output a probability distribution 111 of a data symbol 101b. For example, the probability distribution 111 may include a probability density function (PDF) and/or a cumulative distribution function (CDF), but is not limited thereto. In one or more examples, the neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto.

The probability distribution 111 may indicate the probability of a data symbol that may appear after the data symbol group 101a. The data symbol group 101a may include consecutive data symbols. The data symbol 101b may be positioned after the data symbol group 101a. In one or more examples, the data symbol 101b may be referred to as a current data symbol, and the data symbol group 101a may be referred to as a previous data symbol group.

When compressing the data, the entropy coder 120 may determine the compression bitstream 121 by performing entropy coding (e.g., arithmetic coding) on the data symbol 101b based on the probability distribution 111. As the compression proceeds, the neural model 110 may sequentially determine a probability distribution (e.g., the probability distribution 111) of the current data symbol (e.g., the data symbol 101b) based on the previous data symbol group (e.g., the data symbol group 101a). The entropy coder 120 may determine the compression bitstream 121 by performing entropy coding (e.g., arithmetic coding) on the current data symbol (e.g., the data symbol 101b) based on the probability distribution (e.g., the probability distribution 111). As the compression of the target data 101 proceeds, a value of the compression bitstream 121 may be updated, and as the compression of the last symbol of the target data 101 is completed, the value of the compression bitstream 121 may be finalized.

The electronic device may use the previous data symbol group (e.g., the data symbol group 101a) as context information for predicting the current data symbol (e.g., the data symbol 101b). The context information may act as a conditional probability in the probability distribution 111 and may improve the compression ratio. Even when the size of the target data 101 is small, a high compression ratio may be achieved through the context information.

According to one or more embodiments, the target data 101 may have a small size. For example, a data read unit may be small compared to an existing data write unit. For example, the existing data write unit may be a page (e.g., 4 kilobytes (KB)), and the existing data read unit may be a cache line (e.g., 64B), but the example is not limited thereto. According to one or more embodiments, both data writing and data reading may be performed in the existing data read unit, but the example is not limited thereto. In one or more examples, the size of the target data 101 may be the data read unit (e.g., the cache line), but the example is not limited thereto. According to one or more embodiments, when the size of the target data 101 is small as the cache line, a high compression ratio may be achieved.

When decompressing data, the entropy coder 120 may determine the data symbol 101b by performing entropy decoding (e.g., arithmetic decoding) on the compression bitstream 121 based on the probability distribution 111. As the decompression proceeds, the neural model 110 may sequentially determine a probability distribution (e.g., the probability distribution 111) of the current data symbol (e.g., the data symbol 101b) based on the previous data symbol group (e.g., the data symbol group 101a). The entropy coder 120 may determine the current data symbol (e.g., the data symbol 101b) by performing entropy decoding (e.g., arithmetic decoding) on the compression bitstream 121 based on the probability distribution (e.g., the probability distribution 111).

When a predetermined number of data symbols are not filled at the beginning of compression and decompression, the electronic device may provide a predetermined probability distribution to the entropy coder 120. The entropy coder 120 may perform entropy coding (e.g., arithmetic coding) and entropy decoding (e.g., arithmetic decoding), which may be based on the predetermined probability distribution. As the compression and decompression proceed based on the predetermined probability distribution, a predetermined number of data symbols may be filled in the data symbol group 101a.

According to one or more embodiments, at least a portion of the data symbol group 101a may be filled by data padding at the beginning of compression and decompression, but the example is not limited thereto. In one or more examples, the neural model 110 may predict the probability distribution based on a padding value and the data symbol group 101a including the data symbol at the beginning of compression and decompression. When the predetermined number of data symbols are filled in the data symbol group 101a as compression and decompression proceed, the neural model 110 may predict the probability distribution based on the data symbol group 101a including the predetermined number of data symbols.

According to one or more embodiments, the electronic device may include a host and a memory device. According to one or more embodiments, compression and decompression may be performed by the host (e.g., a memory controller of the host) of the electronic device or the memory device (e.g., a memory controller of the memory device) of the electronic device. When the host performs compression and decompression, a large volume of data may be transmitted through a limited bandwidth in a data input/output process. When the memory device performs compression and decompression, a large volume of data may be stored in a limited storage space.

According to one or more embodiments, the electronic device (e.g., the memory device) may store the compression bitstream 121 in the memory 130. According to one or more embodiments, a compressed memory space may be defined in a memory space. The electronic device may store the compression bitstream 121 in the compressed memory space.

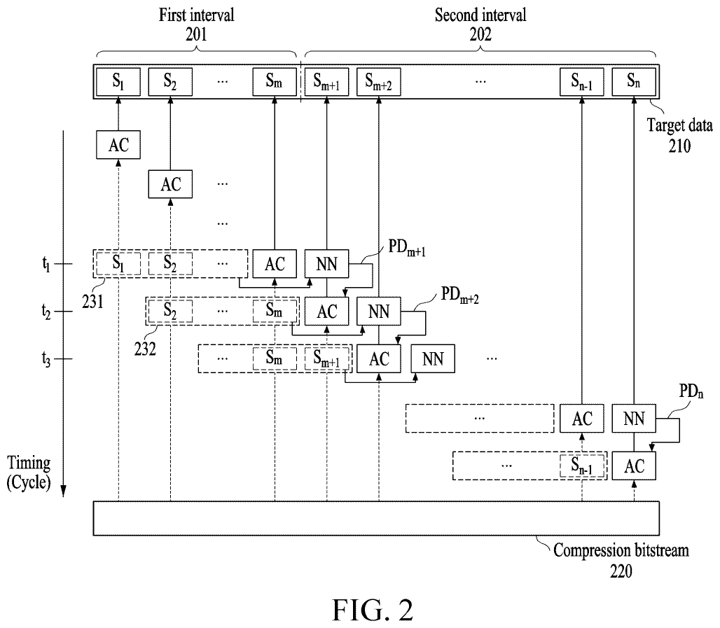

FIG. 2 is a diagram illustrating operation timing of an arithmetic coder and a neural model in a process of decompressing target data, according to one or more embodiments. Referring to FIG. 2, an electronic device (e.g., the host or memory device) may determine target data 210 by decompressing a compression bitstream 220.

The target data 210 may include data symbols Sₖ. The number k may be between 1 and n. The number n may be the total number of data symbols. For example, n may be 64, but is not limited thereto. The data symbols Sₖ may be included in a first interval 201 or a second interval 202. The data symbols Sₖ of the first interval 201 may be generated based on a predetermined probability distribution, and the data symbols Sₖ of the second interval 202 may be generated based on a probability distribution predicted by a neural model NN.

According to one or more embodiments, the prediction of a neural probability distribution may be performed based on the neural model NN that uses a previous data symbol group including a predetermined number (e.g., m−1) of data symbols as input data. For example, the predetermined number may be 8 but is not limited thereto. Before a first time point t₁, the electronic device may determine data symbols (e.g., a data symbol s₁ to a data symbol Sₘ) in the first interval 201 of the target data 210 by decompressing the compression bitstream 220 according to entropy decoding, which may be based on the predetermined probability distribution until a predetermined number of data symbols (e.g., the data symbol s₁ to a data symbol Sₘ₋₁) are secured.

At the first time point t₁, the neural model NN may predict a second probability distribution PDₘ₊₁ of a second data symbol Sₘ₊₁ of the target data 210 to be determined at a second time point t₂ by performing neural probability distribution prediction based on a first previous data symbol group 231 of the target data 210, determined by decompression of a time point interval previous to the first time point t₁. The previous time point interval may include a plurality of time points before the current time point. For example, the previous time point interval corresponding to the first previous data symbol group 231 may include previous time points in which the data symbols S1 to Sₘ₋₁ are determined. At the second time point t₂, an arithmetic coder AC may determine the second data symbol Sₘ₊₁ by decompressing the compression bitstream 220 according to entropy decoding (e.g., arithmetic decoding), which may be based on the compression bitstream 220 and the second probability distribution PDₘ₊₁. The arithmetic coder AC may be an example of the entropy coder. The arithmetic coder AC may complete entropy decoding (e.g., arithmetic decoding) during a single cycle, and the neural model NN may complete probability distribution prediction during the single cycle.

At the second time point t₂, the neural model NN may predict a third probability distribution PDₘ₊₂ of a third data symbol Sₘ₊₂ of the target data 210 to be determined at a third time point t₃ by performing neural probability distribution prediction based on a second previous data symbol group 232 of the target data 210, determined by decompression of a time point interval previous to the second time point t₂. The determination of the second data symbol Sₘ₊₁ by the arithmetic coder AC and the prediction of the third probability distribution PDₘ₊₂ by the neural model NN may be performed in parallel. At the third time point t₃, the arithmetic coder AC may determine the third data symbol Sₘ₊₂ of the target data 210 by decompressing the compression bitstream 220 according to entropy decoding (e.g., arithmetic decoding), which may be based on the compression bitstream 220 and the third probability distribution PDₘ₊₂.

The decompression may be iteratively performed. At the last time point, the arithmetic coder AC may determine a data symbol Sₙ of the target data 210 by decompressing the compression bitstream 220 according to entropy decoding (e.g., arithmetic decoding), which may be based on the compression bitstream 220 and a probability distribution PDₙ. In one or more examples, a time point may refer to an interval of time. For example, referring to FIG. 2, the time point t₁ may refer to an interval of time between t₁ and t₂.

The compression bitstream 220 may be compressed in advance before decompression. For example, the memory device (e.g., the memory controller of the memory device) may receive a write request for the target data 210 from the host before receiving a read request for the target data 210. The memory device may predict each probability distribution of each data symbol Sₖ of the target data 210 by performing neural probability distribution prediction based on the previous data symbol group of each data symbol Sₖ of the target data 210, may determine the compression bitstream 220 by compressing the data symbol Sₖ of the target data 210 according to entropy encoding based on the data symbol Sₖ of the target data 210 and each probability distribution, and may store the compression bitstream 220 in the memory. The memory device may receive a write request for the target data 210 from the host, may read a compression bitstream corresponding to the target data 210 from the memory, and may perform decompression.

According to one or more embodiments, the electronic device (e.g., the host or memory device) may perform neural probability distribution prediction and entropy decoding in parallel by predicting a probability distribution of a data symbol to be determined at a next time point in advance using the neural model NN. In one or more examples, to perform the neural probability distribution prediction, the neural model NN may be trained to predict the probability distribution of the data symbol to be determined at the next time point in advance. For example, the neural model NN may be trained to predict a probability distribution (e.g., the second probability distribution PDₘ₊₁) of a next data symbol (e.g., the data symbol Sₘ₊₁) rather than the current data symbol (e.g., the data symbol Sₘ) based on the previous data symbol group (e.g., the data symbols S₁ to Sₘ₋₁).

This decompression based on pre-prediction may significantly reduce the memory response time (or latency) and decompression time. For example, when the memory device compresses and stores the target data 210 in the memory, the memory device may need to rapidly decompress compressed data (e.g., the compression bitstream 220) in response to the read request of the host and provide the decompressed data to the host. According to one or more embodiments, the memory device may provide the target data 210 to the host with a short response time.

According to one or more embodiments, the arithmetic coder AC and the neural model NN may be designed to have similar computational times. This may minimize a parallel bubble time. For example, the neural model may be designed to include layers that do not have a recursion structure and residual connection. When using a structure that requires computation synchronization, such as the recursion structure and residual connection, the probability distribution prediction by the neural model NN may be delayed compared to decoding by the arithmetic coder AC due to a computation synchronization process.

According to one or more embodiments, the neural model NN may be designed to include a small number of layers. For example, the neural model NN may include four or less layers, but is not limited thereto. When the neural model NN is implemented as a custom logic, an increase in the gate timing of a logic gate in the same layer may not increase a timing margin. A configuration with the small number of layers may enable predicting a probability distribution in a single cycle within a timing margin.

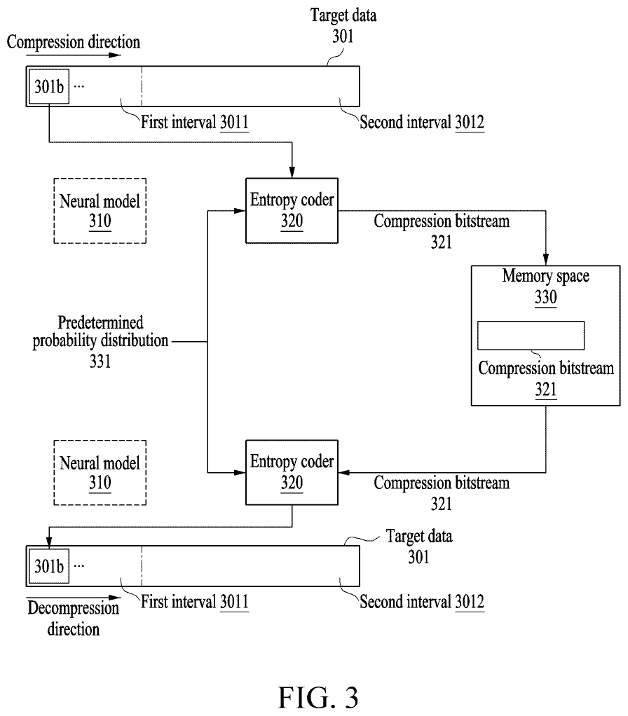

FIG. 3 is a diagram illustrating an example of a decompression process using a predetermined probability distribution, according to one or more embodiments. Referring to FIG. 3, data symbols of target data 301 may be included in a first interval 3011 or a second interval 3012. The data symbols included in the first interval 3011 may be determined based on a predetermined probability distribution 331, and the data symbols included in the second interval 3012 may be determined based on a probability distribution predicted by a neural model 310. FIG. 3 may correspond to a process of determining data symbols of the first interval 3011, and FIG. 1 may correspond to a process of determining data symbols of the second interval 3012.

When compressing the data of a first interval 3301, an entropy coder 320 may determine a compression bitstream 321 by performing entropy coding (e.g., arithmetic coding) on a data symbol 301b of the first interval 3301 based on the predetermined probability distribution 331. When the compression bitstream 321 is finalized as the first interval 3011 and the second interval 3012 are compressed, the electronic device may store the compression bitstream 321 in a memory 330. When decompressing the data, the entropy coder 320 may determine the data symbol 301b by performing entropy decoding (e.g., arithmetic decoding) on the compression bitstream 321 based on the predetermined probability distribution 331.

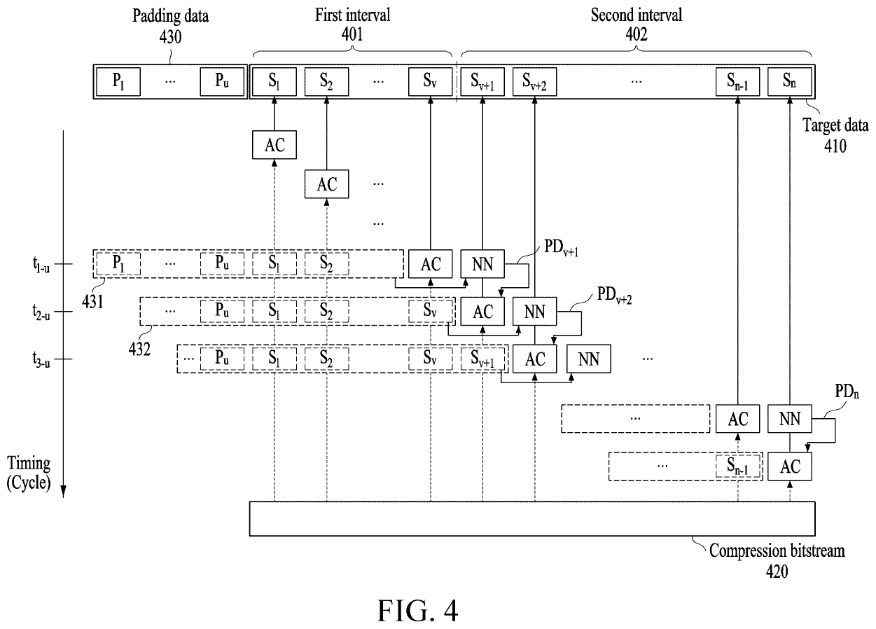

FIG. 4 is a diagram illustrating an example of a decompression process using padding data, according to one or more embodiments. Referring to FIG. 4, an electronic device (e.g., the host or memory device) may determine target data 410 by decompressing a compression bitstream 420.

The target data 410 may include data symbols Sₖ. The number k may be between 1 and n. The number n may be the total number of data symbols. For example, n may be 64, but is not limited thereto. The data symbols Sₖ may be included in a first interval 401 or a second interval 402. The data symbols Sₖ of the first interval 401 may be generated based on a predetermined probability distribution, and the data symbols Sₖ of the second interval 402 may be generated based on a probability distribution predicted by a neural model NN.

According to one or more embodiments, the prediction of a neural probability distribution may be performed based on the neural model NN that uses a previous data symbol group including a predetermined number (e.g., u+v−1) of data symbols as input data. For example, the predetermined number may be 8 but is not limited thereto. This predetermined number may be dynamically adjusted. The electronic device may use padding data 430 to secure the predetermined number of data symbols. In one or more examples, the predetermined number of data symbols may be filled by decompression of the compression bitstream 420 and one or more data paddings. The electronic device may regard padding components P₁ to Pᵤ as the data symbols Sₖ. For example, the electronic device may determine whether the predetermined number of data symbols are secured based on the sum of the number of padding components P₁ to Pᵤ and the number of data symbols Sₖ and may include the padding components P₁ to Pᵤ in the previous data symbol group. The number of padding components P₁ to Pᵤ in the padding data 430 and values thereof may be predetermined.

Before a first time point t₁, the electronic device may determine data symbols (e.g., a data symbol s₁ to a data symbol Sᵥ) in the first interval 401 of the target data 410 by decompressing the compression bitstream 420 according to entropy decoding, which may be based on the predetermined probability distribution until a predetermined number of data symbols (e.g., the padding components P₁ to Pᵤ) are secured.

At the first time point t₁, the neural model NN may predict a second probability distribution PDᵥ₊₁ of a second data symbol Sᵥ₊₁ of the target data 411 to be determined at a second time point t₂ by performing neural probability distribution prediction based on a first previous data symbol group 431 of the target data 410, determined by decompression of a time point interval previous to the first time point t₁. At the second time point t₂, an arithmetic coder AC may determine the second data symbol Sᵥ₊₁ by decompressing the compression bitstream 420 according to entropy decoding (e.g., arithmetic decoding), which may be based on the compression bitstream 420 and the second probability distribution PDᵥ₊₁. The arithmetic coder AC may be an example of the entropy coder.

At the second time point t₂, the neural model NN may predict a third probability distribution PDᵥ₊₂ of a third data symbol Sᵥ₊₂ of the target data 410 to be determined at a third time point t₃ by performing neural probability distribution prediction based on a second previous data symbol group 432 of the target data 410, determined by decompression of a time point interval previous to the second time point t₂. The determination of the second data symbol Sᵥ₊₁ by the arithmetic coder AC and the prediction of the third probability distribution PDᵥ₊₂ by the neural model NN may be performed in parallel. At the third time point t₃, the arithmetic coder AC may determine the third data symbol Sᵥ₊₂ of the target data 410 by decompressing the compression bitstream 420 according to entropy decoding (e.g., arithmetic decoding), which may be based on the compression bitstream 420 and the third probability distribution PDᵥ₊₂.

The decompression may be iteratively performed. At the last time point, the arithmetic coder AC may determine a data symbol Sₙ of the target data 410 by decompressing the compression bitstream 420 according to entropy decoding (e.g., arithmetic decoding), which may be based on the compression bitstream 420 and a probability distribution PDₙ.

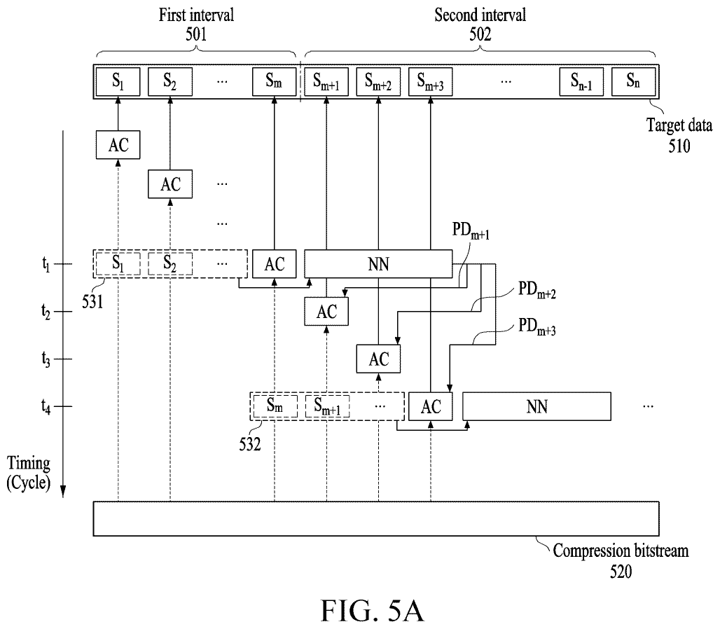

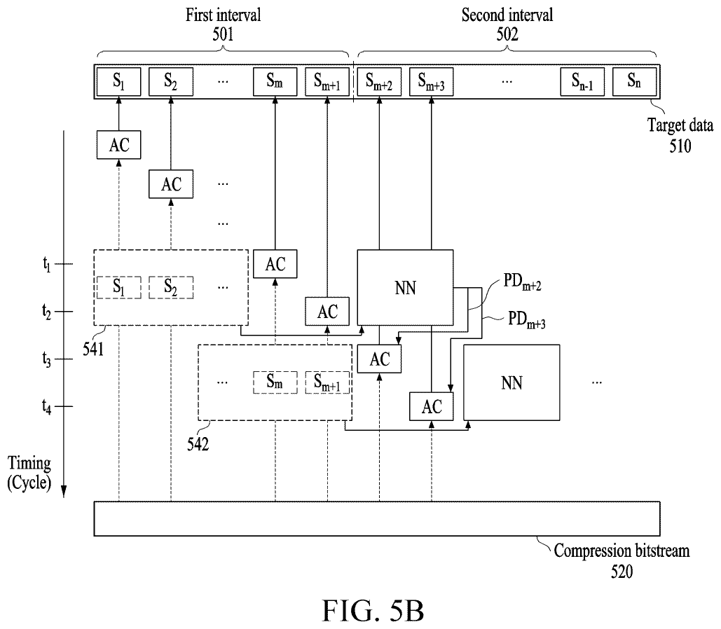

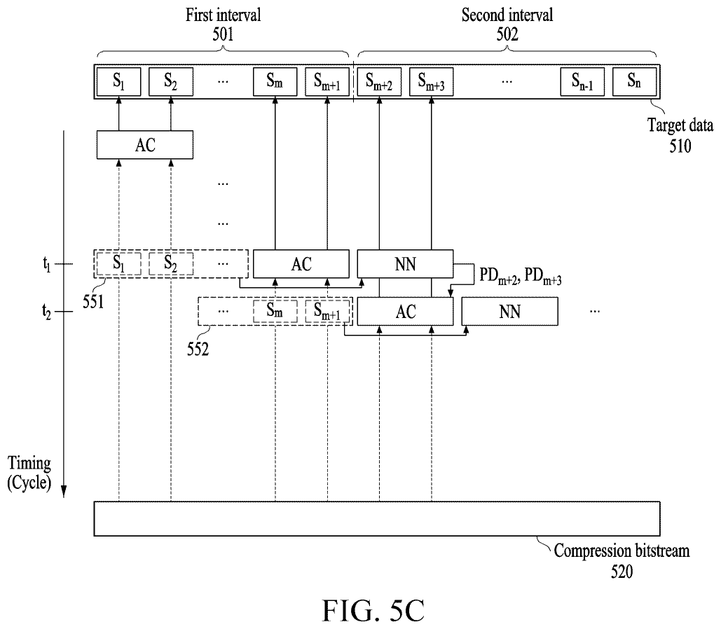

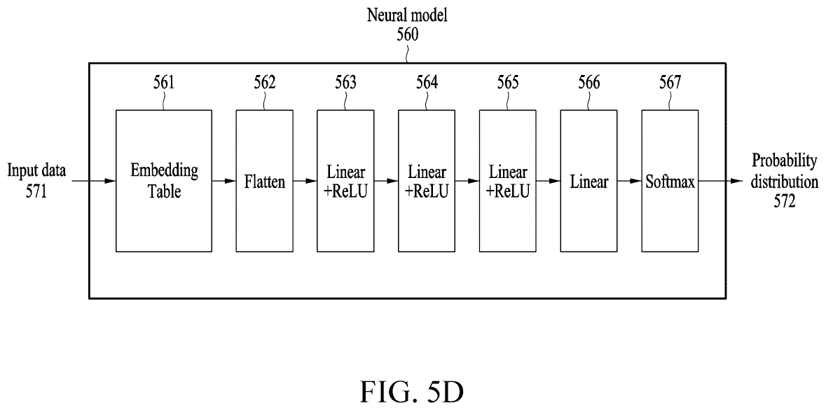

FIG. 5A is a diagram illustrating an example of a decompression process using a neural model for predicting probability distributions of a plurality of data symbols in a single cycle, according to one or more embodiments. Referring to FIG. 5A, an electronic device (e.g., the host or memory device) may determine target data 510 by decompressing a compression bitstream 520.

The target data 510 may include data symbols Sₖ. The number k may be between 1 and n. The number n may be the total number of data symbols. For example, n may be 64, but is not limited thereto. The data symbols Sₖ may be included in a first interval 501 or a second interval 502. The data symbols S₁ to Sₘ of the first interval 501 may be generated based on a predetermined probability distribution, and the data symbols Sₘ₊₁ to Sₙ of the second interval 502 may be generated based on a probability distribution predicted by a neural model NN.

According to one or more embodiments, the neural model NN may predict a plurality of probability distributions during a single cycle. According to one or more embodiments, the neural model NN may be trained to predict the probability distributions of the data symbols to be determined at time points of a plurality of next cycles in advance.

Before a first time point t₁, the electronic device may determine data symbols (e.g., a data symbol s₁ to a data symbol Sₘ) in the first interval 501 of the target data 510 by decompressing the compression bitstream 520 according to entropy decoding, which may be based on the predetermined probability distribution until a predetermined number of data symbols (e.g., the data symbol s₁ to a data symbol Sₘ₋₁) are secured.

At the first time point t₁, the neural model NN may predict a plurality of probability distributions (e.g., the second probability distribution PDₘ₊₁, the third probability distribution PDₘ₊₂, and the fourth probability distribution PDₘ₊₃) of a plurality of data symbols (e.g., the second data symbol Sₘ₊₁, the third data symbol Sₘ₊₂, and the fourth data symbol Sₘ₊₃) of the target data 510 to be determined at a plurality of time points (e.g., the second time point t₂, the third time point t₃, and the fourth time point t₄) by performing neural probability distribution prediction based on a previous data symbol group 531 of the target data 510, determined by decompression of a time point interval previous to the first time point t₁.

At the second time point t₂, an arithmetic coder AC may determine the second data symbol Sₘ₊₁ by decompressing the compression bitstream 520 according to entropy decoding (e.g., arithmetic decoding), which may be based on the compression bitstream 520 and the second probability distribution PDₘ₊₁. At the third time point t₃, an arithmetic coder AC may determine the third data symbol Sₘ₊₂ by decompressing the compression bitstream 520 according to entropy decoding (e.g., arithmetic decoding), which may be based on the compression bitstream 520 and the third probability distribution PDₘ₊₂. At the fourth time point t₄, an arithmetic coder AC may determine the fourth data symbol Sₘ₊₃ by decompressing the compression bitstream 520 according to entropy decoding (e.g., arithmetic decoding), which may be based on the compression bitstream 520 and the fourth probability distribution PDₘ₊₃. The arithmetic coder AC may be an example of the entropy coder. The arithmetic coder AC may complete entropy decoding (e.g., arithmetic decoding) during a single cycle, and the neural model NN may complete probability distribution prediction during the single cycle.

At the fourth time point t₄, the neural model NN may predict a probability distribution of the data symbol Sₖ of the target data 510 to be determined at the next time point by performing neural probability distribution prediction based on a previous data symbol group 532 of the target data 510, determined by decompression of a time point interval previous to the fourth time point t₄. The decompression may be iteratively performed.

FIG. 5B is a diagram illustrating an example of a decompression process using a neural model for predicting probability distributions of a plurality of data symbols in multiple cycles, according to one or more embodiments. Referring to FIG. 5B, an electronic device (e.g., the host or memory device) may determine the target data 510 by decompressing the compression bitstream 520.

According to one or more embodiments, the neural model NN may predict a plurality of probability distributions during multiple cycles. According to one or more embodiments, the neural model NN may be trained to predict the probability distributions of the data symbols to be determined at time points of a plurality of next cycles in advance.

Before a first time point t₁, the electronic device may determine data symbols (e.g., a data symbol s₁ to a data symbol Sₘ) in the first interval 501 of the target data 510 by decompressing the compression bitstream 520 according to entropy decoding, which may be based on the predetermined probability distribution until a predetermined number of data symbols (e.g., the data symbol s₁ to a data symbol Sₘ₋₁) are secured. The data symbols S₁ to Sₘ₊₁ of the first interval 501 may be generated based on a predetermined probability distribution, and the data symbols Sₘ₊₂ to Sₙ of the second interval 502 may be generated based on a probability distribution predicted by the neural model NN.

At the first time point t₁, the neural model NN may predict a plurality of probability distributions (e.g., the third probability distribution PDₘ₊₂ and the fourth probability distribution PDₘ₊₃) of a plurality of data symbols (e.g., the third data symbol Sₘ+₂ and the fourth data symbol Sₘ₊₃) of the target data 510 to be determined at a plurality of time points (e.g., the third time point t₃ and the fourth time point t₄) by performing neural probability distribution prediction based on a previous data symbol group 541 of the target data 510, determined by decompression of a time point interval previous to the first time point t₁. The neural model NN may perform neural probability distribution prediction at the first time point t₁ and the second time point t₂.

At the third time point t₃, the arithmetic coder AC may determine the third data symbol Sₘ₊₂ by decompressing the compression bitstream 520 according to entropy decoding (e.g., arithmetic decoding), which may be based on the compression bitstream 520 and the third probability distribution PDₘ₊₂. At the fourth time point t₄, an arithmetic coder AC may determine the fourth data symbol Sₘ+₃ by decompressing the compression bitstream 520 according to entropy decoding (e.g., arithmetic decoding), which may be based on the compression bitstream 520 and the fourth probability distribution PDₘ₊₃. The arithmetic coder AC may be an example of the entropy coder.

The arithmetic coder AC may complete entropy decoding (e.g., arithmetic decoding) during a single cycle, and the neural model NN may complete probability distribution prediction during multiple cycles. FIG. 5B illustrates an example in which the neural model NN performs probability distribution prediction in two cycles, but is not limited thereto. For example, when the neural model NN has a structure or operating speed at which the neural model NN is unable to complete the probability distribution prediction in a single cycle, parallel processing may be achieved by causing the neural model NN to predict a plurality of probability distributions as shown in FIG. 5B. However, the example is not limited thereto.

At the third time point t₃, the neural model NN may predict probability distributions of the data symbols Sₖ of the target data 510 to be determined at the next time point by performing neural probability distribution prediction based on a previous data symbol group 542 of the target data 510, determined by decompression of a time point interval previous to the fourth time point t₃. The decompression may be iteratively performed.

FIG. 5C is a diagram illustrating an example of a decompression process using a neural model for predicting probability distributions of a plurality of data symbols in a single cycle and an arithmetic coder for performing decoding on the plurality of data symbols in the single cycle, according to one or more embodiments. Referring to FIG. 5C, an electronic device (e.g., the host or memory device) may determine the target data 510 by decompressing the compression bitstream 520.

According to one or more embodiments, the arithmetic coder AC may determine a plurality of data symbols Sₖ through decoding during a single cycle. The neural model NN may predict a plurality of probability distributions during the single cycle. According to one or more embodiments, the neural model NN may be trained to predict the probability distributions of the data symbols to be determined at time points of a plurality of next cycles in advance.

Before a first time point t₁, the electronic device may determine data symbols (e.g., a data symbol s₁ to a data symbol Sₘ) in the first interval 501 of the target data 510 by decompressing the compression bitstream 520 according to entropy decoding, which may be based on the predetermined probability distribution until a predetermined number of data symbols (e.g., the data symbol s₁ to a data symbol Sₘ₋₁) are secured. The data symbols S₁ to Sₘ₊₁ of the first interval 501 may be generated based on a predetermined probability distribution, and the data symbols Sₘ₊₂ to Sₙ of the second interval 502 may be generated based on a probability distribution predicted by the neural model NN.

At the first time point t₁, the neural model NN may predict a plurality of probability distributions (e.g., the third probability distribution PDₘ₊₂ and the fourth probability distribution PDₘ₊₃) of a plurality of data symbols (e.g., the third data symbol Sₘ₊₂ and the fourth data symbol Sₘ₊₃) of the target data 510 to be determined at the second time point t₂ by performing neural probability distribution prediction based on a previous data symbol group 551 of the target data 510, determined by decompression of a time point interval previous to the first time point t₁.

At the second time point t₂, the arithmetic coder AC may determine the third data symbol Sₘ₊₂ and the fourth data symbol Sₘ₊₃ by decompressing the compression bitstream 520 according to entropy decoding (e.g., arithmetic decoding), which may be based on the compression bitstream 520, the third probability distribution PDₘ₊₂ and the fourth probability distribution PDₘ₊₃. The arithmetic coder AC may be an example of the entropy coder.

At the second time point t₂, the neural model NN may predict probability distributions of the data symbols Sₖ of the target data 510 to be determined at the next time point by performing neural probability distribution prediction based on a previous data symbol group 552 of the target data 510, determined by decompression of a time point interval previous to the fourth time point t₂. The decompression may be iteratively performed.

FIG. 5D is a diagram illustrating an example of a structure of a neural model, according to one or more embodiments. Referring to FIG. 5D, a neural model 560 may output a probability distribution 572 based on input data 571. For example, the input data 571 may be a previous data symbol group, and the probability distribution 572 may indicate the probability of a data symbol (e.g., the current data symbol) to appear next to the previous data symbol group.

The neural model 560 may be designed to include layers that do not include a backward re-reference structure (e.g., a recursive structure or residual connection). When using a structure that requires computation synchronization, such as the re-reference structure, the probability distribution prediction by the neural model 560 may be delayed compared to decoding by the entropy coder (e.g., the arithmetic coder) due to the computation synchronization process. According to one or more embodiments, the neural model 560 may be designed to have a computational time (e.g., 1 cycle) that is similar to the arithmetic coder. This feature may minimize a parallel bubble time, which may refer to an idle time in a workflow process having multiple stages (e.g., pipeline).

For example, the neural model 560 may include only layers performing forward operations, such as a multilayer perceptron (MVLP) operation or a convolution operation, as shown in FIG. 5D. The structure for computation synchronization, such as the re-reference structure, may require a certain buffer to refer to a previous operation result for an operation of the current layer. In one or more examples, fewer operation cycles (e.g., 1 cycle) may be difficult to achieve because a branch occurs for buffering. When the neural model 560 needs to be scaled, the neural model 560 may be designed to expand a layer node rather than increasing the number of layers. Node expansion may enable parallel processing, but when the number of layers increases, it may be difficult to achieve fewer operation cycles due to the gate characteristics.

FIG. 5D illustrates a design example of the neural model 560, but the design of the neural model 560 is not limited thereto, and various designs may be applied to the neural model 560 to achieve fewer operation cycles. In the example of FIG. 5D, the neural model 560 may include an embedding table 561, a flatten operation block 562, linear operation and ReLU operation layers 563 to 565, a linear layer 565, and a softmax operation block 567. ReLU is an example of a nonlinear function, and other nonlinear functions may be used.

Since the embedding table 561 may be implemented in the form of a look-up table (LUT), the embedding table 561 may not substantially increase the operation time. The neural model 560 may include four MLP layers, the linear and ReLU layers 563 to 565 and the linear layer 565. The neural model 560 may output the probability distribution 572 via the softmax operation block 567.

In the design example of the neural model 560 of FIG. 5D, activation of each layer may be implemented without a buffer. Accordingly, the neural model 560 may be implemented by a custom logic (e.g., an FPGA or an ASIC) of fewer operation cycles (e.g., 1-cycle), and thus, the neural model 560 may have the same operation cycle as the entropy coder (e.g., an operation coder) and/or parallel processing of the neural model 560 and the entropy coder (e.g., the operation coder) may be enabled.

Table 1 below may show an example of parallel operation time.

TABLE 1

| | | | | | | | Operation |
|---|---|---|---|---|---|---|---|
| n | d | M | s | p | T | t | cycle |
| 64 | 8 | 1 | 1 | 4 | 1 | 1 | 64 |

The number n may denote a compressed data length or a compression unit (e.g., a block or a chunk). For example, n may denote the number of symbols represented by the compressed data (e.g., the compression bitstream). Table 1 may show an example in which n is 65 (e.g., 64B). d may represent the length of the input data 571. For example, d may denote the number of symbols included in the previous data symbol. For example, each symbol may have a size of 1, but is not limited thereto. Table 1 may show an example in which d is 8. The parameter m may denote the number of probability distributions 572. For example, m may denote the number of probability distributions 572 (e.g., PDF and CDF). FIG. 1 may show an example in which m is 1. In the example of Table 1, eight symbols each having the size of 1 B may be used as the input data 571, and a probability of 32 symbols having a size of 256 B may be represented by one probability distribution 572.

The parameter s may denote a time point difference between the data symbol of the probability distribution 572 and the input data 571. For example, the input data 571 may indicate the previous data symbol group, and the probability distribution 572 may indicate a probability of the current data symbol. When the current data symbol is a data symbol immediately after the previous data symbol group, s may be 1 as shown in Table 1. The parameter p may denote the number of padding components used as padding data. Table 1 may show an example in which p is 4.

T may indicate a cycle used for an inference operation of the neural model 560. Table 1 may show an example in which the neural model 560 infers the probability distribution 572 corresponding to the input data 571 during one cycle. The parameter t may denote an operation cycle of the entropy coder (e.g., the arithmetic coder). FIG. 1 may show an example in which one cycle is consumed for each of entropy encoding (e.g., arithmetic encoding) and entropy decoding (e.g., arithmetic decoding) of the entropy coder.

The operation cycle may be calculated by n*t+(n−d)/m*T. FIG. 1 may show an example in which a final operation cycle of the neural model 560 is 64 cycles. According to one or more embodiments, only 64 cycles may be required to process 64B, and 1-cycle/byte may be achieved. In one or more examples, a response time to output the first symbol may be one cycle.

Table 2 may show an example of a sequential operation time unlike Table 1.

TABLE 2

| | | | | | | | Operation |
|---|---|---|---|---|---|---|---|
| n | d | m | S | p | T | T | cycle |
| 64 | 8 | 1 | — | — | 8 | 1 | 512 |

The example of Table 2 may show an operation cycle according to sequential operations of an existing model (e.g., a long short-term memory (LSTM) model) to which a constraint (e.g., operation synchronization exclusion) of the neural model 560 is not applied. In the example of Table 2, T may be 8 due to a structural limitation of the existing model. In one or more examples, the operation cycle may increase due to the sequential operation. Accordingly, in the example of Table 2, a final operation cycle may be 512.

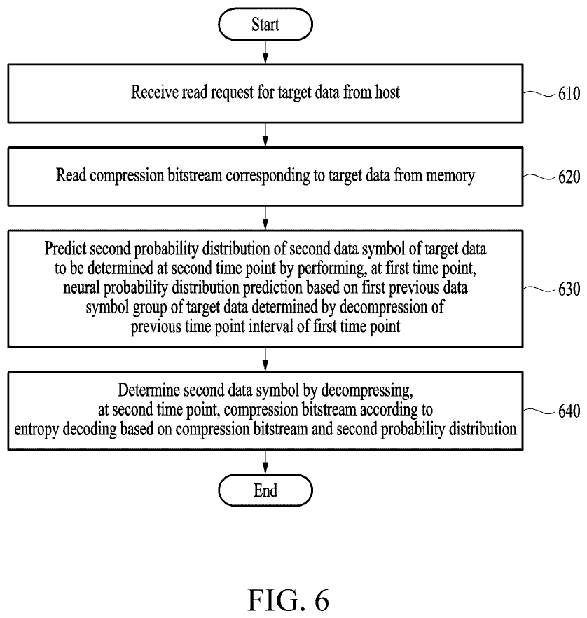

FIG. 6 is a flowchart of a method performed by a memory device, according to one or more embodiments. Referring to FIG. 6, an electronic device (e.g., the memory device) may receive a read request for target data from a host in operation 610, may read a compression bitstream corresponding to the target data from a memory in operation 620, may predict, at a first time point, a second probability distribution of a second data symbol of the target data to be determined at a second time point by performing neural probability distribution prediction based on a first previous data symbol group of the target data, determined by decompression of a time point interval previous to the first time point in operation 630, and may determine, at the second time point, a second data symbol by decompressing the compression bitstream according to entropy decoding, which may be based on the compression bitstream and the second probability distribution in operation 640.

At the second time point, the electronic device may predict a third probability distribution of a third data symbol of the target data to be determined at the third time point by performing neural probability distribution prediction based on a second previous data symbol group of the target data, determined by decompression of a time point interval previous to the second time point, and at the third time point, may determine a third data symbol of the target data by decompressing the compression bitstream according to entropy decoding, which may be based on the compression bitstream and the third probability distribution.

The electronic device may determine the second data symbol and predict the third probability distribution in parallel.

Before receiving the read request, the electronic device may receive a write request for the target data from the host, may predict each probability distribution of each data symbol of the target data by performing neural probability distribution prediction based on the previous data symbol group of each data symbol of the target data, may determine the compression bitstream by compressing each data symbol of the target data according to entropy encoding based on each probability distribution and each data symbol of the target data, and may store the compression bitstream in the memory.

The electronic device may perform neural probability distribution prediction based on the neural model that uses the previous data symbol group including a predetermined number of data symbols as input data. Before the first time point, the electronic device may determine the data symbol of the target data by decompressing the compression bitstream according to entropy decoding, which may be based on the predetermined probability distribution until the predetermined number of data symbols are secured.

The predetermined number of data symbols may be filled by decompression of the compression bitstream and one or more data paddings.

The neural model used for neural probability distribution prediction may include layers that do not have a recursive structure and residual connection.

Operation 630 may include an operation of predicting the second probability distribution of the second data symbol and the third probability distribution of the third data symbol of the target data to be determined at the second time point and the third time point by performing neural probability distribution prediction based on the first previous data symbol group at the first time point. At the third time point, the electronic device may determine the third data symbol by decompressing the compression bitstream according to entropy decoding, which may be based on the third probability distribution and the compression bitstream.

Operation 630 may include an operation of predicting the second probability distribution of the second data symbol and the third probability distribution of the third data symbol of the target data to be determined at the second time point by performing neural probability distribution prediction based on the first previous data symbol group at the first time point. Operation 640 may include an operation of determining the second data symbol and the third data symbol by decompressing the compression bitstream according to entropy decoding, which may be based on the compression bitstream, the second probability distribution, and the third probability distribution at the second time point.

The compression bitstream may be stored in a compressed memory space of the memory.

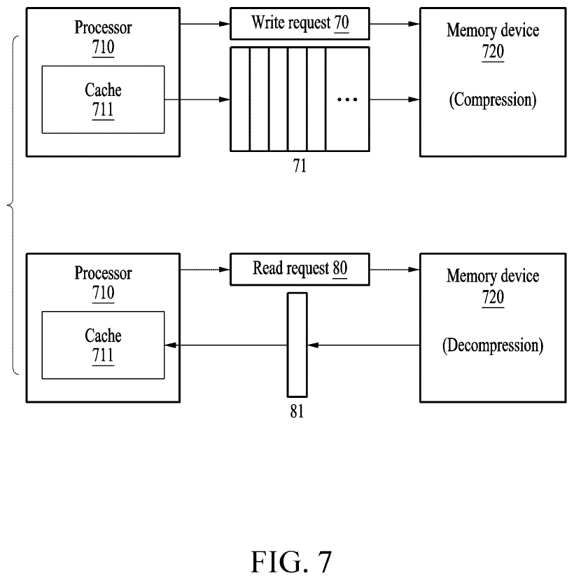

FIG. 7 is a diagram illustrating an example of an operation of a memory device based on a write request and a read request of a processor, according to one or more embodiments. Referring to FIG. 7, a processor 710 may transmit, to a memory device 720, a write request 70 for data values 71 of a cache 711 to be written to the memory device 720. The memory device 720 may store the data values 71 in the memory of the memory device 720 in response to the write request 70 of the processor 710. The memory device 720 may compress and store the data values 71 in the memory. The memory space may be efficiently used due to data compression.

Among the data values 71, when a data value 81 is required, the processor 710 may transmit, to the memory device 720, a read request 80 for the data value 81 to be read from the memory device 720. The data value 81 may be a part of the data values 71. For example, the size of the data values 71 may be a page (e.g., 4 KB) corresponding to the write unit, and the size of the data value 81 may be a cache line (e.g., 64B) corresponding to the read unit, but the example is not limited thereto.

The memory device 720 may store the data values 71 according to the size of the data value 81. The memory device 720 may compress each of the data values 71 according to the size of the data value 81 and may store the compressed data having the same size as the data value 81. The memory device 720 may decompress the compressed data corresponding to the data value 81 in response to the read request 80 for the data value 81 and may provide the decompressed data to the processor 710. The processor 710 may store the first data value 81 in the cache 711.

When the data of the write request 70 having a large size is comprehensively compressed, the compressed data is stored, and the data having a small size is requested in response to the read request 80, the compressed data having the large size may need to be decompressed, and the data having the small size of the read request 80 may need to be extracted from the decompressed data. In one or more examples, the processing speed for the read request 80 may not be fast enough. According to one or more embodiments, compression and decompression may be performed with the small size of the read request 80. Accordingly, an inefficient operation of decompressing data having a large size and extracting data having a small size from the decompressed data may become efficient. The memory device 720 may more rapidly process the read request 80 by reducing the amount of operations to process the read request 80.

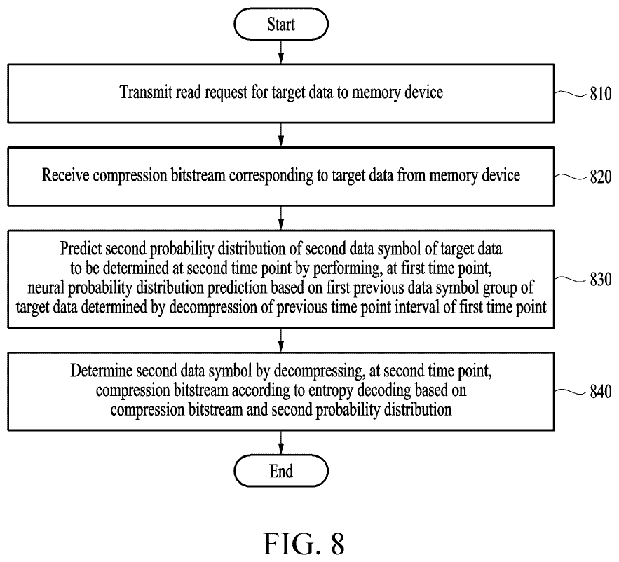

FIG. 8 is a flowchart of a method performed by a host, according to one or more embodiments. Referring to FIG. 8, an electronic device (e.g., the host) may transmit a read request for target data to a memory device in operation 810, may receive a compression bitstream corresponding to the target data from the memory device in operation 820, may predict, at a first time point, a second probability distribution of a second data symbol of the target data to be determined at a second time point by performing neural probability distribution prediction based on a first previous data symbol group of the target data, determined by decompression of a time point interval previous to the first time point in operation 830, and may determine, at the second time point, a second data symbol by decompressing the compression bitstream according to entropy decoding, which may be based on the compression bitstream and the second probability distribution in operation 840.

At the second time point, the electronic device may predict a third probability distribution of a third data symbol of the target data to be determined at the third time point by performing neural probability distribution prediction based on a second previous data symbol group of the target data, determined by decompression of a time point interval previous to the second time point, and at the third time point, may determine a third data symbol of the target data by decompressing the compression bitstream according to entropy decoding, which may be based on the compression bitstream and the third probability distribution.

The electronic device may determine the second data symbol and predict the third probability distribution in parallel.

Before receiving the read request, the electronic device may receive a write request for the target data from the host, may predict each probability distribution of each data symbol of the target data by performing neural probability distribution prediction based on the previous data symbol group of each data symbol of the target data, may determine the compression bitstream by compressing each data symbol of the target data according to entropy encoding based on each probability distribution and each data symbol of the target data, and may store the compression bitstream in the memory.

The electronic device may perform neural probability distribution prediction based on the neural model that uses the previous data symbol group including a predetermined number of data symbols as input data. Before the first time point, the electronic device may determine the data symbol of the target data by decompressing the compression bitstream according to entropy decoding, which may be based on the predetermined probability distribution until the predetermined number of data symbols are secured.

The predetermined number of data symbols may be filled by decompression of the compression bitstream and one or more data paddings.

The neural model used for neural probability distribution prediction may include layers that do not have a recursive structure and residual connection.

Operation 830 may include an operation of predicting the second probability distribution of the second data symbol and the third probability distribution of the third data symbol of the target data to be determined at the second time point and the third time point by performing neural probability distribution prediction based on the first previous data symbol group at the first time point. At the third time point, the electronic device may determine the third data symbol by decompressing the compression bitstream according to entropy decoding, which may be based on the third probability distribution and the compression bitstream.

Operation 830 may include an operation of predicting the second probability distribution of the second data symbol and the third probability distribution of the third data symbol of the target data to be determined at the second time point by performing neural probability distribution prediction based on the first previous data symbol group at the first time point. Operation 840 may include an operation of determining the second data symbol and the third data symbol by decompressing the compression bitstream according to entropy decoding, which may be based on the compression bitstream, the second probability distribution, and the third probability distribution at the second time point.

The compression bitstream may be stored in a compressed memory space of the memory.

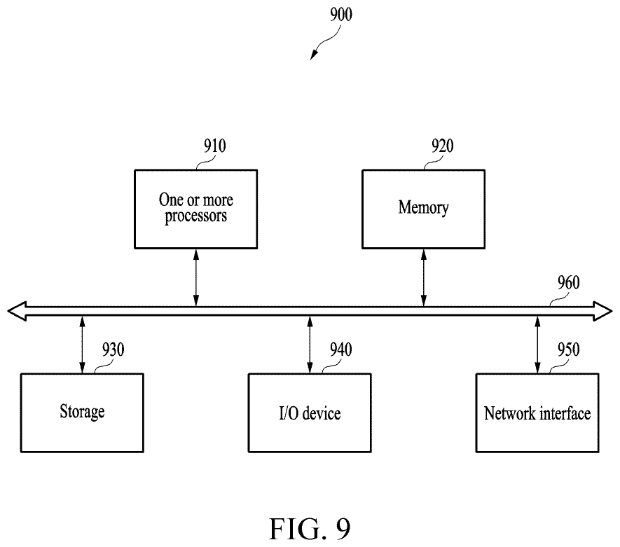

FIG. 9 is a diagram illustrating an example of a configuration of an electronic device, according to one or more embodiments. Referring to FIG. 9, an electronic device 900 may include one or more processors 910, a memory 920, a storage 930, an input/output (I/O) device 940, and a network interface 950, which may communicate with each other via a communication bus 960. For example, the electronic device 900 may be implemented as at least a portion of a mobile device, such as a mobile phone, a smartphone, a personal digital assistant (PDA), a netbook, a tablet computer, and a laptop computer, a wearable device, such as a smartwatch, a smartband, and smartglasses, and a computing device, such as a desktop and a server.

The one or more processors 910 may execute instructions stored in the memory 920 or the storage 930. The instructions, when executed by the one or more processors 910, may cause the electronic device 900 to perform the operations described with reference to FIGS. 1 to 8.

According to one or more embodiments, the one or more processors 910 may correspond to a host. The one or more processors 910 or the host (e.g., a memory controller of the one or more processors 910 or the host) may execute instructions stored in the memory 920 or the storage 930. The instructions, when executed by the one or more processors 910, may cause the electronic device 900 (e.g., the memory controller of the one or more processors 910 or the host) to perform the operations described with reference to FIGS. 1 to 8.

According to one or more embodiments, the memory 920 may include a memory device. For example, the memory device may be an external memory device or an extended memory device. For example, the memory device may be a compute express link (CXL) memory device, but the example is not limited thereto. The CXL memory device may be connected to the one or more processors 910 (e.g., the host) via a CXL interface and/or a peripheral component interconnect express (PCI-e) interface.

According to one or more embodiments, the memory device (e.g., the memory controller of the memory device) may include one or more internal processors and an internal memory. The one or more internal processors may execute instructions stored in the internal memory. The instructions, when executed by the one or more internal processors, may cause the electronic device 900 to perform the operations described with reference to FIGS. 1 to 8.

For example, the one or more internal processors may implement a neural model and/or an entropy coder (e.g., the arithmetic coder). For example, the neural model and/or the entropy coder may be implemented as digital circuitry separated from and/or integrated into the memory controller (e.g., the memory controller of the memory device). For example, the neural model and/or the entropy coder may be physically implemented by analog and/or digital circuitry including at least one of a logic gate, an integrated circuit, a microprocessor, a microcontroller, a memory circuit, a passive electronic component, an active electronic component, an optical component, or a similar component thereto. For example, an FPGA and/or an ASIC may be used to implement a custom logic, and the custom logic may perform at least a portion of a function of the neural model and/or the entropy coder.

The memory 920 may include a computer-readable storage medium or a computer-readable storage device. The memory 920 may store instructions to be executed by the one or more processors 910 and may store related information while software and/or an application is executed by the electronic device 900. For example, the memory 920 may correspond to a first memory pool. A second memory pool may include a memory of a second processing group of the one or more processors 910.

The storage 930 may include a computer-readable storage medium or a computer-readable storage device. The storage 930 may store a greater volume of information than the memory 920 and may store the information for a long period of time. For example, the storage 930 may include a magnetic hard disk, an optical disk, flash memory, a floppy disk, or other non-volatile memories known in the art.

The I/O device 940 may receive an input from the user in traditional input manners through a keyboard and a mouse, and in new input manners such as a touch input, a voice input, and an image input. For example, the I/O device 940 may include a keyboard, a mouse, a touchscreen, a microphone, or any other device that detects the input from the user and transmits the detected input to the electronic device 900. The I/O device 940 may provide an output of the electronic device 900 to the user through a visual, auditory, or haptic channel. The I/O device 940 may include, for example, a display, a touchscreen, a speaker, a vibration generator, or any other device configured to provide the output to the user. The network interface 950 may communicate with an external device via a wired or wireless network.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, an FPGA, a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and multiple types of processing elements. For example, the processing device may include a plurality of processors, or a single processor and a single controller. In one or more examples, different processing configurations are possible, such as parallel processors.

The software may include a computer program, a piece of code, an instruction, or some combination thereof, to independently or uniformly instruct or configure the processing device to operate as desired. Software and data may be stored in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter.

The above-described hardware devices may be configured to act as one or more software modules in order to perform the operations of the above-described examples, or vice versa.

As described above, although the embodiments have been described with reference to the limited drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

What is claimed is:

1. A processor-implemented method performed by a memory device, the method comprising:
receiving a read request for target data from a host;
reading a compression bitstream corresponding to the target data from a memory;
predicting, at a first time point, a second probability distribution of a second data symbol of the target data by performing a neural probability distribution prediction based on a first previous data symbol group of the target data, determined by decompression of a time point interval previous to the first time point; and
determining, at a second time point later than the first time point, the second data symbol by decompressing the compression bitstream according to entropy decoding based on the compression bitstream and the second probability distribution.

2. The method of claim 1, further comprising:
predicting, at the second time point, a third probability distribution of a third data symbol of the target data by performing a neural probability distribution prediction based on a second previous data symbol group of the target data, determined by decompression of a time point interval previous to the second time point; and
determining, at a third time point later than the second time point, the third data symbol by decompressing the compression bitstream according to entropy decoding based on the compression bitstream and the third probability distribution.

3. The method of claim 2, wherein the determining the second data symbol and the predicting the third probability distribution are performed in parallel.

4. The method of claim 1, further comprising:
receiving a write request for the target data from the host before receiving the read request;
predicting each probability distribution of each data symbol of the target data by performing a neural probability distribution prediction based on a previous data symbol group of each data symbol of the target data;
determining the compression bitstream by compressing each data symbol of the target data according to entropy encoding based on each probability distribution and each data symbol of the target data; and
storing the compression bitstream in the memory.

5. The method of claim 1, wherein the neural probability distribution prediction is performed by a neural model that uses a previous data symbol group including a predetermined number of data symbols as input data, and
wherein the method further comprises:
determining a data symbol of the target data by decompressing the compression bitstream according to entropy decoding based on a predetermined probability distribution until the predetermined number of data symbols are secured before the first time point.

6. The method of claim 5, wherein the predetermined number of data symbols are filled by decompression of the compression bitstream and one or more data paddings.

7. The method of claim 1, wherein a neural model used for the neural probability distribution prediction includes a plurality of layers that does not have a recursion structure and a residual connection.

8. The method of claim 1, wherein the predicting the second probability distribution comprises, at the first time point, predicting the second probability distribution and a third probability distribution of the second data symbol and a third data symbol of the target data, by performing the neural probability distribution prediction based on the first previous data symbol group.

9. The method of claim 8, further comprising:
determining, at a third time point, the third data symbol by decompressing the compression bitstream according to entropy decoding based on the compression bitstream and the third probability distribution.

10. The method of claim 1, wherein the predicting the second probability distribution comprises, at the first time point, predicting the second probability distribution and a third probability distribution of the second data symbol and a third data symbol of the target data, respectively, by performing the neural probability distribution prediction based on the first previous data symbol group.

11. The method of claim 10, wherein the determining the second data symbol comprises, at the second time point, determining the second data symbol and the third data symbol by decompressing the compression bitstream according to entropy decoding based on the compression bitstream, the second probability distribution, and the third probability distribution.

12. The method of claim 1, wherein the compression bitstream is stored in a compressed memory space of the memory.

13. A processor-implemented method performed by a host, the method comprising:
transmitting a read request for target data to a memory device;
receiving a compression bitstream corresponding to the target data from the memory device;
predicting, at a first time point, a second probability distribution of a second data symbol of the target data by performing a neural probability distribution prediction based on a first previous data symbol group of the target data, determined by decompression of a time point interval previous to the first time point; and
determining, at a second time point later than the first time point, the second data symbol by decompressing the compression bitstream according to entropy decoding based on the compression bitstream and the second probability distribution.

14. The method of claim 13, further comprising:
predicting, at the second time point, a third probability distribution of a third data symbol of the target data by performing a neural probability distribution prediction based on a second previous data symbol group of the target data, determined by decompression of a time point interval previous to the second time point; and
determining, at a third time point later than the second time point, the third data symbol by decompressing the compression bitstream according to entropy decoding based on the compression bitstream and the third probability distribution.

15. A memory device comprising:
memory configured to store instructions; and
one or more processors operatively coupled to the memory;
wherein the instructions, when executed by the one or more processors individually or collectively, cause the memory device to:
receive a write request for target data from a host,
read a compression bitstream corresponding to the target data from the memory,
predict, at a first time point, a second probability distribution of a second data symbol of the target data by performing a neural probability distribution prediction based on a first previous data symbol group of the target data, determined by decompression of a time point interval previous to the first time point, and
determine, at a second time point later than the first time point, the second data symbol by decompressing the compression bitstream according to entropy decoding based on the compression bitstream and the second probability distribution.

16. The memory device of claim 15, wherein the instructions, when executed by the one or more processors individually or collectively, cause the memory device to:
predict, at the second time point, a third probability distribution of a third data symbol of the target data by performing a neural probability distribution prediction based on a second previous data symbol group of the target data, determined by decompression of a time point interval previous to the second time point, and
determine, at a third time point later than the second time point, the third data symbol by decompressing the compression bitstream according to entropy decoding based on the compression bitstream and the third probability distribution.

17. The memory device of claim 16, wherein the determining the second data symbol and the predicting the third probability distribution are performed in parallel.

18. The memory device of claim 15, wherein a neural model used for the neural probability distribution prediction includes a plurality of layers that do not have a recursion structure and a residual connection.

19. The memory device of claim 15, wherein the instructions, when executed by the one or more processors individually or collectively, cause the memory device to predict, at the first time point, the second probability distribution and a third probability distribution of the second data symbol and a third data symbol of the target data by performing the neural probability distribution prediction based on the first previous data symbol group.

20. The memory device of claim 19, wherein the instructions, when executed by the one or more processors individually or collectively, cause the memory device to determine, at a third time point, the third data symbol by decompressing the compression bitstream according to entropy decoding based on the compression bitstream and the third probability distribution.
